(19) United States
(12) Patent Application Publication
(10) Pub. No.: US 2025/0253280 A1
(43) Pub. Date: Aug. 7, 2025

(54) SINTERABLE ELECTRICAL CONTACT ON A SEMICONDUCTOR SUBSTRATE

(71) Applicant: Infineon Technologies AG, Neubiberg (DE)

(72) Inventors: Stefan Woehlert, Villach (AT); Paul Frank, Finkenstein am Faaker See (AT); Bernhard Markus Weidgans, Bernhardswald (DE); Frederik Otto, Olfen (DE)

(21) Appl. No.: 19/023,865

(22) Filed: Jan. 16, 2025

(30) Foreign Application Priority Data
Feb. 6, 2024 (DE) 102024103256.1

(51) Int. Cl. H01L 23/00

(52) U.S. Cl. CPC H01L 24/29; H01L 24/27; H01L 24/32; H01L 24/83; H01L 2224/2745; H01L 2224/27462; H01L 2224/27848; H01L 2224/29084; H01L 2224/29124; H01L 2224/29139; H01L 2224/29147; H01L 2224/29155; H01L 2224/29166; H01L 2224/32227; H01L 2224/8384

(57) ABSTRACT

A semiconductor device includes a semiconductor substrate and a sinterable electrical contact disposed over the semiconductor substrate. The sinterable electrical contact includes a copper-based layer disposed over the semiconductor substrate. The copper-based layer has a thickness between 50 nm and 1000 nm. The sinterable electrical contact further includes a titanium-based layer disposed between the copper-based layer and the semiconductor substrate. A final functional layer for bonding the sinterable electrical contact by sintering is either the copper-based layer or a silver-based layer disposed over the copper-based layer.

### TECHNICAL FIELD

This disclosure relates to semiconductor devices having sinterable electrical contacts, and in particular to chip metallization techniques for providing high-quality electrical sinter contacts.

### BACKGROUND

In general, a problem with electrically contacting a semiconductor substrate by sintering is that the sintered connection is porous, which means that it is typically more susceptible to corrosion than, for example, a solder connection. For this reason, a sintered connection must be protected against moisture and oxygen, which may not be necessary to the same extent with a soldered connection. For example, it is known to use a nickel-vanadium layer as a protective layer in the metallization stack that forms the sinterable contact.

Nevertheless, the quality of the subsequent sinter bond connection in terms of, e.g., robustness and/or corrosion resistance is sensitive to changes in the parameters of the sintering process. Therefore, it is an ongoing challenge to provide a sinterable electrical contact on a semiconductor substrate which enables the generation of a high-quality sinter bond connection within a wide process window of the sintering process (i.e., also under suboptimal sinter conditions, in particular also under air).

### SUMMARY

According to an aspect of the disclosure, a semiconductor device includes a semiconductor substrate and a sinterable electrical contact disposed over the semiconductor substrate. The sinterable electrical contact includes a copper-based layer disposed over the semiconductor substrate. The copper-based layer has a thickness between 50 nm and 1000 nm. The sinterable electrical contact further includes a titanium-based layer disposed between the copper-based layer and the semiconductor substrate. A final functional layer for bonding the sinterable electrical contact by sintering is either the copper-based layer itself or a silver-based layer disposed over the copper-based layer.

According to a further aspect of the disclosure, a system includes a semiconductor device as specified above and a device carrier comprising a contact pad. The sinterable electrical contact is bonded to the contact pad by a sinter bond connection.

According to a further aspect of the disclosure, a method of forming a sinterable electrical contact on a semiconductor substrate comprises depositing a titanium-based layer over the semiconductor substrate. A copper-based layer is formed over the titanium-based layer. The copper-based layer has a thickness between 50 nm and 1000 nm. A final functional layer for bonding the sinterable electrical contact by sintering is either the copper-based layer itself or a silver-based layer is formed over the copper-based layer, wherein a final functional layer for bonding the sinterable electrical contact by sintering is the silver-based layer.

According to a further aspect of the disclosure, a method of attaching a semiconductor device as specified above to a device carrier including a contact pad comprises sintering the sinterable electrical contact to the contact pad.

### BRIEF DESCRIPTION OF THE DRAWINGS

In the drawings, like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross sectional view of an example of a semiconductor device including a semiconductor substrate and a sinterable electrical contact.

FIG. 2 is a schematic cross sectional view of a specific example of the semiconductor device of FIG. 1.

FIG. 3 is a schematic cross sectional view of another specific example of the semiconductor device of FIG. 1.

FIG. 4 is a schematic cross sectional view of an example of a system including a semiconductor device bonded to a device carrier by sintering.

FIG. 5 is a flowchart illustrating stages of an exemplary method of forming a sinterable electrical contact on a semiconductor substrate.

FIG. 6 is a flowchart illustrating stages of an exemplary method of attaching a semiconductor device to a device carrier by sintering.

### DETAILED DESCRIPTION

It is to be understood that the features of the various exemplary embodiments and examples described herein may be combined with each other unless specifically noted otherwise.

As used in this specification, the terms “electrically connected” or “electrically coupled” or similar terms are not meant to mean that the elements are directly contacted together; intervening elements may be provided between the “electrically connected” or “electrically coupled” elements, respectively. However, in accordance with the disclosure, the above-mentioned and similar terms may, optionally, also have the specific meaning that the elements are directly contacted together, i.e. that no intervening elements are provided between the “electrically connected” or “electrically coupled” elements, respectively.

Further, the words “over” or “beneath” or similar terms with regard to a part, element or material layer formed or located or arranged “over” or “beneath” a surface may be used herein to mean that the part, element or material layer be located (e.g. placed, formed, arranged, deposited, etc.) “directly on” or “directly under”, e.g. in direct contact with, the implied surface. The words “over” or “beneath” or similar terms used with regard to a part, element or material layer formed or located or arranged “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

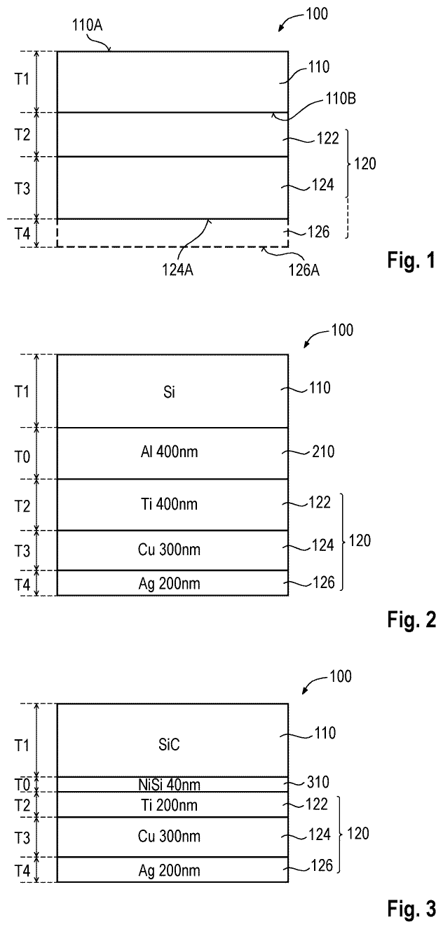

Referring to FIG. 1, a semiconductor device 100 includes a semiconductor substrate 110. The semiconductor device 100 further includes a sinterable electrical contact 120 disposed over the semiconductor substrate 110. The meaning of “sinterable electrical contact” is that the electrical contact is configured to be connected to an electrically conductive structure (such as, e.g., a contact pad on a device carrier) by a sintering process.

The semiconductor substrate 110 may have a front side 110A and a backside 110B. For example, the sinterable electrical contact 120 is arranged on the backside 110B of the semiconductor substrate 110. In this case the sinterable electrical contact 120 is also referred to as backside metallization in the art.

In other examples (not shown), the sinterable electrical contact 120 may be arranged additionally or exclusively on the front side 110A of the semiconductor substrate 110. The sinterable electrical contact 120 may then be referred to as a front side metallization of the semiconductor substrate 110. For illustrative purposes, the sinterable electrical contact 120 is shown in FIG. 1 as the backside metallization, but it can also represent the front side metallization of the semiconductor substrate 110.

The semiconductor substrate 110 may be a semiconductor chip or a semiconductor wafer, for example. The semiconductor substrate 110 may include one or more electrical components such as, e.g., one or more integrated circuits (not shown), which individually or in combination control a current flow between the front side 110A and the backside 110B of the semiconductor substrate 110. Such semiconductor devices 100 are also referred to as vertical devices. In other examples, the semiconductor substrate 110 may include one or more electrical components which individually or in combination control a current flow in the lateral direction. Such semiconductor devices 100 are also referred to as lateral (or horizontal) devices. In lateral devices one or more sinterable electrical contacts 120 may, e.g., be provided only at one main side (either the front side 110A or the backside 110B) of the semiconductor substrate 110.

For example, the electrical component may be a power component. In this case the semiconductor device 100 is a semiconductor power device 100. Semiconductor power devices 100 may control voltages equal to or greater than 50V, 100V, 500V, 750V, or 1000V, for example.

The electrical component (not shown) integrated in the semiconductor substrate 110 may, e.g., be a transistor or a transistor array. For example, the semiconductor device 100 may be a discrete transistor device. The electrical component integrated in the semiconductor substrate 110 may, e.g., be a MOSFET (metal oxide semiconductor field-effect transistor) or an IGBT (insulated gate bipolar transistor).

In other examples, the electrical component (not shown) integrated in the semiconductor substrate 110 may include or represent a diode. In this case, the semiconductor device 100 may represent a discrete diode device, e.g. a power diode. For example, the semiconductor device 100 may include or be a fast-switching EMCON (EMitter-CONtrolled) diode.

In other words, the semiconductor substrate 110 may, e.g., be a diode or transistor power chip and/or the semiconductor device 100 may, e.g., be a (discrete) diode or transistor power package.

The semiconductor substrate 110 includes or is of a semiconductor material, for example Si, SiC, SiGe, Ge, GaN, GaAs, InAs, etc., and other compound semiconductors. In particular, the semiconductor substrate 110 may comprise or be of Si or a WBG (Wide Bandgap) semiconductor material such as, e.g., SiC, GaN, and many III-V and II-VI compound semiconductors having a high bandgap.

In some examples, the sinterable electrical contact 120 may form a load contact of the semiconductor device 100. For example, the sinterable electrical contact 120 may form a source contact or an emitter contact of the semiconductor device 100 (e.g., a MOSFET or an IGBT, respectively). In addition or alternatively, the sinterable electrical contact 120 may form a drain contact or a collector contact of the semiconductor device 100 (e.g., a MOSFET or an IGBT, respectively).

The sinterable electrical contact 120 includes a titanium-based layer 122 and a copper-based layer 124. Here and in the following, the expression “X-based layer” means that the layer is of the material X or of an alloy which includes the material X as the majority alloying material.

The copper-based layer 124 is disposed over the semiconductor substrate 110. The titanium-based layer 122 is disposed between the copper-based layer 124 and the semiconductor substrate 110. In some examples, the copper-based layer 124 may directly adjoin the titanium-based layer 122.

In a first case, a final functional layer for bonding the sinterable electrical contact 120 by sintering is the copper-based layer 124. In this case, a surface of the final functional layer facing away from the substrate 110 may, e.g., be formed by a surface 124A of the copper-based layer 124. That is, the final functional layer may provide an exposed surface for bonding the sinterable electrical contact 120 by a sintering process.

The final functional layer of the sinterable electrical contact 120 is the layer which interacts with the sinter bond material (not shown) during the sintering process. While in many examples, the final functional layer (therefore) provides for the exposed surface of the sinterable electrical contact 120, it is also possible that the final functional layer may be coated with a top layer (not shown) which may, e.g., serve as a protective layer that facilitates sintering, e.g., because it does not form a stable metal oxide at the sinter process temperature even when being processed in air.

In a second case, a silver-based layer 126 may, e.g., be disposed over the copper-based layer 124. In this case, the final functional layer for bonding the sinterable electrical contact 120 by sintering is the silver-based layer 126. Similar as in the first case, a surface 126A of the silver-based layer 126 facing away from the substrate 110 may be an exposed surface of the sinterable electrical contact 120 or may, e.g., be covered by a coating which does not affect the functionality for sintering of the final functional layer (here: the silver-based layer 126).

The copper-based layer 124 has a thickness T3 between 50 nm and 1000 nm. In specific examples, the thickness T3 of the copper-based layer 124 may, e.g., be between 100 nm and 500 nm, in particular, between 200 nm and 400 nm.

It is to be noted that the thickness T3 of the copper-based layer 124 may be considerably smaller compared to a thickness of a copper layer in an electrical contact that is a solderable contact. Copper layers in solderable electrical contacts are typically at least partly “consumed” during the soldering process and therefore need to have a higher minimum thickness.

The sinterable electrical contact 120 may, e.g., be a non-solderable contact. This means that the sinterable electrical contact 120 could not be bonded to any electrically conductive structure (e.g., a contact pad on a device carrier) by a soldering process.

The titanium-based layer 122 may have a thickness T2 between 100 nm and 500 nm, in particular between 200 nm and 400 nm, for example.

The titanium-based layer 122 acts as a diffusion barrier and (optionally) as an adhesion promoter (at least if a Ti—Cu interface is present). In many examples, the copper-based layer 124 and the titanium-based layer 122 are in direct contact to each other, i.e. provide such interface. However, in other examples, one or more other layers (e.g., a tungsten layer, not shown) may optionally be arranged between the titanium-based layer 122 and the copper-based layer 124.

The silver-based layer 126, if present, may have a thickness T4 between 20 nm and 1500 nm, in particular, between 100 or 200 nm and 400 or 1000 nm.

Conventional sinterable electrical contacts often use a nickel-vanadium-based layer arranged between the semiconductor substrate 110 and a final silver-based layer 126. Nickel-vanadium-based layers are weakened by oxygen, which may reach the layer during or after the sintering process. A final silver layer 126 does not prevent oxygen to reach the nickel-vanadium-based layer, since oxygen may penetrate through the silver layer 126.

It has been found that the interface between a copper-based layer 124 and a final silver layer is not mechanically weakened by oxygen to the same extent as the conventional nickel-vanadium-based layer. This could possibly be due to the fact that the cohesion between a final silver layer and a copper oxide is stronger than that between a final silver layer and a nickel oxide.

In some examples, the sinterable electrical contact 120 does not include any nickel-vanadium-based layer. In other words, the copper-based layer 124 may be used to replace layers such as the nickel-vanadium-based layer conventionally used in sinterable electrical contacts. Avoiding a nickel-vanadium-based layer enhances the robustness of the sinterable electrical contact.

Further, in contrast to a (conventional) nickel-vanadium-based layer, the copper-based layer 124 may form the final functional layer for sintering (see the first case described above). This may be particularly attractive if moving from a silver paste sintering process to a copper paste sintering process, since a copper-based final functional layer 124 sintered with a copper paste is expected to provide a particularly high mechanical stability of the sinter bond connection (as will be described in more detail below).

Further, a contact layer (not shown in FIG. 1, see layer 210 of FIGS. 2 and 3, for example) may be arranged between the semiconductor substrate 110 and the titanium-based layer 122. The contact layer may include or be of a material which provides good electrical contact between the sinterable electrical contact 120 and the semiconductor substrate 110.

FIG. 2 shows a specific example of the semiconductor device 100 of FIG. 1. In this example the semiconductor substrate 110 may, e.g., include or be of silicon (Si). The sinterable electrical contact 120 comprises or is composed of the titanium-based layer 122, the copper-based layer 124 and the silver-based layer 126. In the specific example shown, the titanium-based layer 122 is of titanium with, e.g., T2=400 nm, the copper-based layer 124 is of copper with, e.g., T3=300 nm and the silver-based layer 126 is of silver with, e.g., T4=200 nm.

Further, in particular if the semiconductor substrate 110 is of silicon, a contact layer formed by an aluminum-based layer 210 may be arranged between the sinterable electrical contact 120 and the substrate 110. The aluminum-based layer 210 may, e.g., have a thickness TO between 100 nm and 500 nm, in particular between 200 nm and 400 nm. The aluminum-based layer 210 may serve as an electrical contact to the silicon substrate 110. The aluminum-based layer 210 may be of aluminum, for example. In the example shown, T0=400 nm.

Referring to FIG. 3, another specific example of the semiconductor device 100 is shown. In this example the semiconductor substrate 110 comprises or is of silicon carbide (SiC), for example.

In this case an aluminum-based layer is not needed for electrical contact formation to the semiconductor substrate 110. Rather, the electrical contact to the semiconductor substrate 110 may be formed by a nickel-silicon-(NiSi—) based layer 310, for example.

The nickel-silicon-based layer 310 may, e.g., be disposed between the titanium-based layer 122 and the semiconductor substrate 110. The nickel-silicon-based layer 310 may have a thickness TO between 20 nm and 200 nm, in particular 30 nm and 80 nm. In the specific example shown, the nickel-silicon-based layer 310 may have a thickness T0=40 nm, for example.

The sinterable electrical contact 120 in FIG. 3 includes the titanium-based layer 122, the copper-based layer 124 and (optionally) the silver-based layer 126. The titanium-based layer 122 may, e.g., be of titanium and may, e.g., have a thickness T2=200 nm. The copper-based layer 124 may, e.g., be of copper and may, e.g., have a thickness T3=300 nm. The silver-based layer 126 (if present) may, e.g., be of silver and may, e.g., have a thickness T4=200 nm.

All specific thickness values set out in FIGS. 2 and 3 may be varied within the limits recited above and/or within ranges of ±50%, ±30%, ±10%, for example.

In all examples it is possible to avoid any nickel-vanadium-based layer, which is conventionally used for contact formation. This may eliminate a risk of producing a sinter bond connection of low mechanical properties due to a degradation of a nickel-vanadium-based layer by oxygen.

Further, in all examples the sinterable electrical contact may be tin-free and/or may not include a tin-based layer. Tin-based layers are often used in solderable electrical contacts.

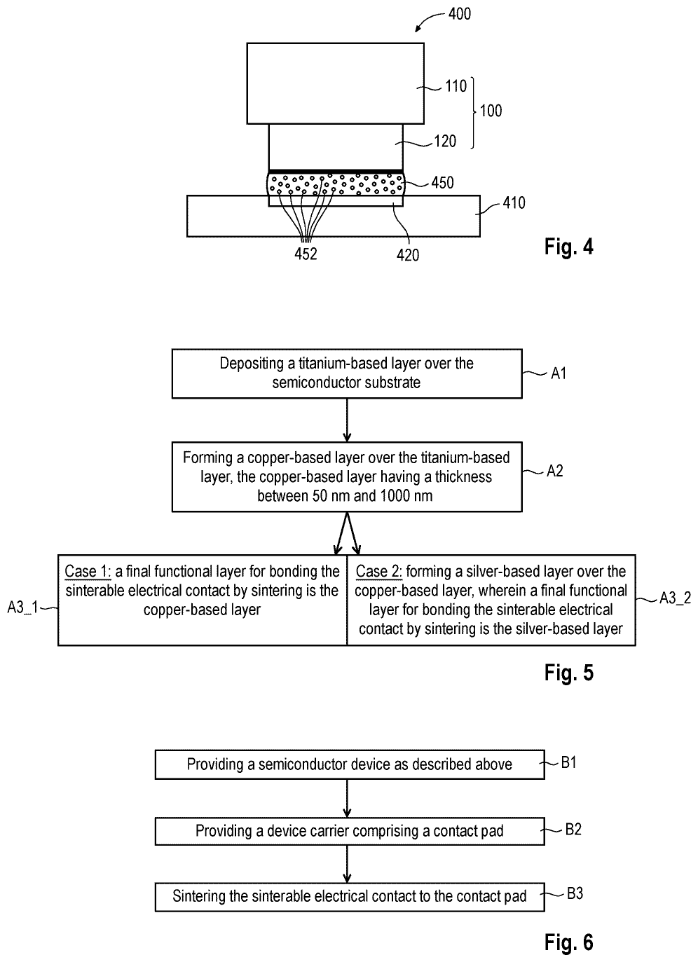

FIG. 4 illustrates a system 400 including a semiconductor device 100 bonded to a device carrier 410 by sintering.

The device carrier 410 may be any device carrier for mounting a semiconductor device 100, in particular a device carrier 410 configured to mount a power semiconductor device 100. For example, the semiconductor device carrier 410 may, e.g., be a leadframe, a printed circuit board (PCB) or a ceramic-based carrier such as, e.g., a copper-plated ceramic carrier, e.g. a DBC (direct bonded copper) carrier. The device carrier 410 includes a contact pad 420. The contact pad 420 may but does not need to be a distinct part of the device carrier 410 but may, e.g., merely represent a zone or area of the device carrier 410 on which the semiconductor device 100 is to be mounted.

The sinterable electrical contact 120 is bonded to the contact pad 420 by a sinter bond connection 450. The sinter bond connection 450 includes metal sinter particles 452. The metal sinter particles 452 are in contact with each other and electrically connect both to the final functional layer of the sinterable electrical contact 120 and to the contact pad 420. As mentioned before, the final functional layer of the sinterable electrical contact 120 may be formed by the copper-based layer 124 or by the silver-based layer 126 (and may be provided with an exposed surface 124A of the copper-based layer 124 or with an exposed surface 126A of the silver-based layer 126, for example).

The metal sinter particles 452 of the sinter bond connection 150 may include or be of silver. In this case, the final functional layer may, e.g., be the silver-based layer 126. However, it is also possible to use a sinter bond connection 450 made of silver sinter particles 452 for a sinterable electrical contact 120 in which the final functional layer is the copper-based layer 124.

In other examples, the sinter bond connection 450 includes copper-based sinter particles 452. In one possibility, the copper-based sinter particles 452 may connect to a silver-based final functional layer, e.g. to the surface 126A of the silver-based layer 126.

In other examples, the sinterable electrical contact 120 may be provided with a copper-based final functional layer. In this case, the copper-based sinter particles 452 may directly connect to the surface 124A of the copper-based layer 124. A direct copper-to-copper connection may provide for high mechanical properties of the sinter bond connection 450. In particular, oxygen degradation of the mechanical properties of the sinterable electrical contact 120 may be strongly reduced by combining a copper-based sinter bond connection 450 with a copper-based termination of the sinterable electrical contact 120.

Referring to FIG. 5, a method of forming a sinterable electrical contact 120 on a semiconductor substrate 110 includes, at A1, depositing a titanium-based layer 122 over the semiconductor substrate 110. Prior to the deposition of the titanium-based layer 122, several processes may be carried out which may depend on the material of the semiconductor substrate 110.

In case of Si-based technologies (compare FIG. 2), initially a pre-cleaning process may be performed. Pre-cleaning may, e.g., be performed as an in-situ H₂ reactive plasma etching or as an ex-situ HF wet etching, for example. By the pre-cleaning process, native SiO₂ is removed at the exposed surface of the semiconductor substrate 110.

Subsequently, the aluminum-based layer 210 (or any other contact layer) may, e.g., be deposited over the cleaned surface of the semiconductor substrate 110. Deposition of aluminum may, e.g., be performed by physical vapor deposition (PVD) such as sputter deposition. During aluminum deposition the wafer temperature may be increased to around 200-400° C. by, e.g., increasing the chuck temperature and/or the applied sputter power of the deposition process. The increased substrate temperature results in the recrystallization of the silicon at the interface to the aluminum-based layer 210 and the formation of an ohmic contact between the silicon substrate 110 and the aluminum-based layer 210.

After the deposition of the titanium-based layer 122 at A1, the copper-based layer 124 is formed over the titanium-based layer 122 at A2. The copper-based layer 124 may be formed by sputter deposition or by galvanic plating, for example. The copper-based layer 124 has a thickness between 50 nm and 1000 nm.

The aluminum-based layer 210, the titanium-based layer 122 and the copper-based layer 124 may, e.g., be sputter deposited in different modules (process chambers) of a PVD cluster tool. In this case, the semiconductor substrate 110 may be kept under vacuum between the deposition of the various layers to avoid contamination and oxidation of the interfaces. This may avoid the risk of delamination of adjacent layers.

In silicon carbide (Sic) technologies (compare FIG. 3), a contact formation prior to the deposition of the titanium-based layer 122 at A1 may be done by the deposition of the Nisi-based layer 310. The NiSi-based layer 310 may have a composition of 11% wt Si and 89% wt Ni, for example. The formation of the NiSi-based layer 310 may be done in combination with a laser thermal annealing (LTA) process.

Subsequently, one or more ex-situ cleaning processes may be performed prior to the deposition of the titanium-based layer at A1. The ex-situ cleaning process(es) may be used to remove carbon resulting from a Ni/SiC reaction or to remove oxide layer(s). Further, still prior to the deposition of the titanium-based layer 122 at A1, an in-situ H₂ plasma etching pre-cleaning of the surface of the NiSi-based layer 310 may be performed.

Subsequently, the titanium-based layer 122 (at A1) and the copper-based layer 124 (at A2) may be deposited, e.g., sputter deposited without vacuum break. Deposition of the individual layers 122, 124, 126 may be performed the same way as described above for the silicon-based technology.

According to the first case, the final functional layer for bonding the sinterable electrical contact 120 by sintering is the copper-based layer 124 (at A3_1). Alternatively, according to the second case, the silver-based layer 126 is subsequently applied over the copper-based layer 124. In this case, the final functional layer for bonding the sinterable electrical contact by sintering is the silver-based layer 126 (at A3_2).

As mentioned above, A3_1 may enable a bare copper termination of the sinterable electrical contact 120 combined with copper sintering. This specific option allows to avoid the silver-based layer 126 and may provide for high mechanical quality sintering.

In all examples in which a silver-based layer 126 is used, the provision of the copper-based layer 124 allows to reduce the thickness T4 of the silver-based layer 126 compared to a situation in which no copper-based layer 124 would be present. For example, without a copper-based layer 124, a thicker silver-based layer 126 (e.g. T4≥800 nm) would be necessary to reach the desired robustness of the sinterable electrical contact 120. However, high T4 values lead to increased cycle time for the deposition and thus to higher cost.

Referring to FIG. 6, a method of attaching the semiconductor device 100 to a device carrier 410 may include, at B1, providing a semiconductor device 100 as described above, and providing, at B2, a device carrier 410 including a contact pad 420.

At B3, the sinterable electrical contact 120 is sintered to the contact pad 420. Sintering may include applying the sintering material (e.g., silver particles or copper particles or a mixture of silver and copper particles) on the contact pad 420 to which the semiconductor device 100 is to be sintered.

The sintering material (silver and/or copper particles 452) may, for example, be contained in a sintering paste. If the metal sinter particles 452 are dispersed in a volatile solution, the (porous) sinter bond connection 450 may contain or comprise the metal sinter particles 452 alone after sintering. If the metal sinter particles 452 are dispersed in an epoxy material, the epoxy material may cure during sintering so that the sinter bond connection 450 includes a cured epoxy matrix in which the metal sinter particles 452 are embedded.

During the sintering process, which may be performed by applying a pressure to the semiconductor substrate 110 and the device carrier 410 and/or by applying energy (e.g., heat, radiation, etc.), the metal particles 452 bond together. Typically, the metal particles 452 are not melted during the sintering process and no intermetallic phases are formed between the sintered material and the surface of the final functional layer and/or the surface of the contact pad 420.

A process window for sintering may include parameters (sintering specifications) which must be met. Such parameters may include the pressure to be applied, the heat to be applied (sintering temperature), the atmosphere under which the sintering process is to be performed (e.g., under vacuum or air) as well as the sintering time, for example. The wider the process window, the easier and more reliable the sintering process is. This is particularly important for customers receiving bare dies (bare chips) where the chip manufacturer has no control over the subsequent sintering process. For example, due to the enhanced stability of the sinterable electrical contact 120, the sintering specifications may allow sintering under air.

The following examples pertain to further aspects of the disclosure:

Example 1 is a semiconductor device including a semiconductor substrate and a sinterable electrical contact disposed over the semiconductor substrate. The sinterable electrical contact includes a copper-based layer disposed over the semiconductor substrate. The copper-based layer has a thickness between 50 nm and 1000 nm. The sinterable electrical contact further includes a titanium-based layer disposed between the copper-based layer and the semiconductor substrate. A final functional layer for bonding the sinterable electrical contact by sintering is either the copper-based layer itself or a silver-based layer disposed over the copper-based layer.

In Example 2, the subject matter of Example 1 can optionally include wherein the sinterable electrical contact is a non-solderable contact.

In Example 3, the subject matter of Example 1 or 2 can optionally include wherein the semiconductor substrate is a silicon substrate or a silicon carbide substrate.

In Example 4, the subject matter of any preceding Example can optionally include wherein the semiconductor device is a power device and the sinterable electrical contact is a load contact of the power device.

In Example 5, the subject matter of any preceding Example can optionally include wherein the copper-based layer and the titanium-based layer are in direct contact to each other.

In Example 6, the subject matter of any preceding Example can optionally include wherein the copper-based layer has a thickness between 100 nm and 500 nm, in particular between 200 nm and 400 nm.

In Example 7, the subject matter of any preceding Example can optionally include wherein the titanium-based layer has a thickness between 100 nm and 500 nm, in particular between 200 nm and 400 nm.

In Example 8, the subject matter of any preceding Example can optionally include wherein the final functional layer provides an exposed surface for bonding the sinterable electrical contact by sintering.

In Example 9, the subject matter of any preceding Example can optionally include wherein the silver-based layer has a thickness between 20 nm and 1500 nm, in particular between 200 nm and 400 nm.

In Example 10, the subject matter of any preceding Example can optionally further include an aluminum-based layer disposed between the titanium-based layer and the semiconductor substrate, in particular a silicon substrate.

In Example 11, the subject matter of Example 10 can optionally include wherein the aluminum-based layer has a thickness between 100 nm and 500 nm, in particular 200 nm and 400 nm.

In Example 12, the subject matter of any preceding Example can optionally further include wherein nickel-silicon-based layer disposed between the titanium-based layer and the semiconductor substrate, in particular a silicon carbide substrate.

In Example 13, the subject matter of Example 12 can optionally include wherein the nickel-silicon-based layer has a thickness between 20 nm and 200 nm, in particular 30 nm and 80 nm.

In Example 14, the subject matter of any preceding Example can optionally include wherein the sinterable electrical contact does not include a nickel-vanadium-based layer and/or a tin-based layer.

In Example 15, the subject matter of any preceding Example can optionally include wherein the sinterable electrical contact is a backside metallization and/or a front side metallization of the semiconductor device or forms a part thereof.

Example 16 is a system that includes a semiconductor device as recited above and a device carrier comprising a contact pad. The sinterable electrical contact is bonded to the contact pad by a sinter bond connection.

In Example 17, the subject matter of Example 16 can optionally include wherein the sinter bond connection comprises silver-based sinter particles.

In Example 18, the subject matter of Example 17 can optionally include wherein the final functional layer is the silver-based layer.

In Example 19, the subject matter of Example 19 can optionally include wherein the sinter bond connection comprises copper-based sinter particles.

In Example 20, the subject matter of Example 16 can optionally include wherein the final functional layer is the copper-based layer.

Example 21 is a method of forming a sinterable electrical contact on a semiconductor substrate comprises depositing a titanium-based layer over the semiconductor substrate. A copper-based layer is formed over the titanium-based layer. The copper-based layer has a thickness between 50 nm and 1000 nm. A final functional layer for bonding the sinterable electrical contact by sintering is the copper-based layer or a silver-based layer is formed over the copper-based layer, wherein a final functional layer for bonding the sinterable electrical contact by sintering is the silver-based layer.

In Example 22, the subject matter of Example 21 can optionally include wherein the semiconductor substrate is a silicon substrate, the method further comprising depositing an aluminum-based layer over the silicon substrate before depositing the titanium-based layer, wherein during depositing the aluminum-based layer the silicon substrate is heated to a temperature between 200° C. and 400° C.

In Example 23, the subject matter of Example 21 can optionally include wherein the semiconductor substrate is a silicon carbide substrate, the method further comprising depositing a nickel-silicon-based layer over the silicon carbide substrate before depositing the titanium-based layer, and annealing the silicon-carbide substrate and the nickel-silicon-based layer.

In Example 24, the subject matter of Example 21 can optionally include wherein the copper-based layer is formed by sputtering or by galvanic plating.

Example 25 is a method of attaching a semiconductor device of any of Examples 1 to 15 to a device carrier comprising a contact pad. The method comprises sintering the sinterable electrical contact to the contact pad.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate; and
a sinterable electrical contact disposed over the semiconductor substrate, wherein the sinterable electrical contact comprises:
a copper-based layer disposed over the semiconductor substrate, the copper-based layer having a thickness between 50 nm and 1000 nm; and
a titanium-based layer disposed between the copper-based layer and the semiconductor substrate, wherein a final functional layer for bonding the sinterable electrical contact by sintering is either the copper-based layer or a silver-based layer disposed over the copper-based layer.

2. The semiconductor device of claim 1, wherein the sinterable electrical contact is a non-solderable contact.

3. The semiconductor device of claim 1, wherein the semiconductor substrate is a silicon substrate or a silicon carbide substrate.

4. The semiconductor device of claim 1, wherein the semiconductor device is a power device and the sinterable electrical contact is a load contact of the power device.

5. The semiconductor device of claim 1, wherein the copper-based layer and the titanium-based layer are in direct contact to each other.

6. The semiconductor device of claim 1, wherein the copper-based layer has a thickness between 100 nm and 500 nm.

7. The semiconductor device of claim 1, wherein the titanium-based layer has a thickness between 100 nm and 500 nm.

8. The semiconductor device of claim 1, wherein the final functional layer provides an exposed surface for bonding the sinterable electrical contact by sintering.

9. The semiconductor device of claim 1, wherein the silver-based layer has a thickness between 20 nm and 1500 nm.

10. The semiconductor device of claim 1, further comprising:
an aluminum-based layer disposed between the titanium-based layer and the semiconductor substrate,
wherein the semiconductor substrate is a silicon substrate.

11. The semiconductor device of claim 10, wherein the aluminum-based layer has a thickness between 100 nm and 500 nm.

12. The semiconductor device of claim 1, further comprising:
a nickel-silicon-based layer disposed between the titanium-based layer and the semiconductor substrate,
wherein the semiconductor substrate is a silicon carbide substrate.

13. The semiconductor device of claim 12, wherein the nickel-silicon-based layer has a thickness between 20 nm and 200 nm.

14. The semiconductor device of claim 1, wherein the sinterable electrical contact is devoid of a nickel-vanadium-based layer and/or a tin-based layer.

15. The semiconductor device of claim 1, wherein the sinterable electrical contact is a backside metallization and/or a front side metallization of the semiconductor device or forms a part thereof.

16. A system, comprising:
the semiconductor device of claim 1; and
a device carrier comprising a contact pad,
wherein the sinterable electrical contact is bonded to the contact pad by a sinter bond connection.

17. The system of claim 16, wherein the sinter bond connection comprises silver-based sinter particles.

18. The system of claim 17, wherein the final functional layer is a silver-based layer.

19. The system of claim 16, wherein the sinter bond connection comprises copper-based sinter particles.

20. The system of claim 19, wherein the final functional layer is the copper-based layer.

21. A method of forming a sinterable electrical contact on a semiconductor substrate, the method comprising:
depositing a titanium-based layer over the semiconductor substrate; and
forming a copper-based layer over the titanium-based layer, the copper-based layer having a thickness between 50 nm and 1000 nm,
wherein a final functional layer for bonding the sinterable electrical contact by sintering is the copper-based layer, or the method further comprises forming a silver-based layer over the copper-based layer such that the final functional layer is the silver-based layer.

22. The method of claim 21, wherein the semiconductor substrate is a silicon substrate, the method further comprising:
depositing an aluminum-based layer over the silicon substrate before depositing the titanium-based layer,
wherein during the depositing of the aluminum-based layer, the silicon substrate is heated to a temperature between 200° C. and 400° C.

23. The method of claim 21, wherein the semiconductor substrate is a silicon carbide substrate, the method further comprising:
depositing a nickel-silicon-based layer over the silicon carbide substrate before depositing the titanium-based layer; and
annealing the silicon-carbide substrate and the nickel-silicon-based layer.

24. The method of claim 21, wherein the copper-based layer is formed by sputtering or by galvanic plating.

25. A method, comprising:
providing a semiconductor device having a semiconductor substrate and a sinterable electrical contact disposed over the semiconductor substrate, wherein the sinterable electrical contact comprises: a copper-based layer disposed over the semiconductor substrate, the copper-based layer having a thickness between 50 nm and 1000 nm; and a titanium-based layer disposed between the copper-based layer and the semiconductor substrate; and
sintering the copper-based layer to a contact pad of a device carrier, or forming a silver-based layer over the copper-based layer and sintering the silver-based layer to the contact pad.
